(19) United States
(12) Patent Application Publication
(10) Pub. No.: US 2026/0026051 A1
(43) Pub. Date: Jan. 22, 2026

(54) SEMICONDUCTOR STRUCTURE INCLUDING DIFFERENT BARRIER LAYERS AND METHOD FOR MANUFACTURING THE SAME

(71) Applicant: Taiwan Semiconductor Manufacturing Company, Ltd., Hsinchu (TW)

(72) Inventors: Cheng Ju TSAI, Hsinchu (TW); Ching Yu CHEN, Hsinchu (TW); Wei-Ting CHANG, Hsinchu (TW); Jiang-He XIE, Hsinchu (TW)

(73) Assignee: Taiwan Semiconductor Manufacturing Company, Ltd., Hsinchu (TW)

(21) Appl. No.: 18/778,407

(22) Filed: Jul. 19, 2024

(51) Int. Cl. H01L 29/06; H01L 29/10; H01L 29/20; H01L 29/66; H01L 29/778

(52) U.S. Cl. CPC H10D 62/102; H10D 30/015; H10D 30/475; H10D 62/221; H10D 62/8503

(57) ABSTRACT

A method for manufacturing a semiconductor structure includes: forming a channel layer on a substrate; forming a first barrier layer on the channel layer, the first barrier layer being made of a material represented by Alₓ₁Ga₁₋ₓ₁N; forming a doped layer on the first barrier layer; forming a second barrier layer over the first barrier layer opposite to the channel layer, the second barrier layer being made of a material represented by Alₓ₂Ga₁₋ₓ₂N, x2 being greater than x1; and forming a third barrier layer on the second barrier layer opposite to the first barrier layer, the third barrier layer being made of a material represented by Alₓ₃Ga₁₋ₓ₃N, x3 being smaller than x2.

### BACKGROUND

A high-electron-mobility transistor (HEMT) has a heterojunction structure by stacking two semiconductor materials with different band gaps, such as aluminum gallium nitride (AlGaN) and gallium nitride (GaN), on each other. At an interface between AlGaN and GaN, a two-dimension electron gas (2DEG) is formed and serves as a channel for the HEMT.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 9 are schematic views illustrating intermediate stages of the method for manufacturing the semiconductor structure in accordance with some embodiments as depicted in FIG. 1.

FIG. 10 is a schematic view illustrating a modified semiconductor structure in accordance with some embodiments made by the method as depicted in FIG. 1.

FIG. 11 is a schematic graph illustrating aluminum content in different elements of the semiconductor structure shown in FIG. 10.

FIG. 12 is a schematic graph illustrating a band diagram of different elements of the semiconductor structure shown in FIG. 10.

FIG. 13 is a flow diagram illustrating a method for manufacturing a semiconductor structure in accordance with some embodiments.

FIGS. 14 to 19 are schematic views illustrating intermediate stages of the method for manufacturing the semiconductor structure in accordance with some embodiments as depicted in FIG. 13.

FIG. 20 is a schematic diagram illustrating a modified semiconductor structure in accordance with some embodiments made by the method as depicted in FIG. 13.

FIG. 21 is a graph illustrating aluminum content in different elements of the semiconductor structure shown in FIG. 20.

FIG. 22 is a graph illustrating a band diagram of different elements of the semiconductor structure shown in FIG. 20.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a semiconductor structure including different barrier layers, and a method for manufacturing thereof. In accordance with some embodiments, the semiconductor structure of the present disclosure is a high-electron-mobility transistor (HEMT), but is not limited thereto. The different barrier layers are configured to help confine electrons at an interface between a channel layer and the barrier layers, so as to permit the HEMT to have an improved breakdown voltage and a dynamic on-state resistance.

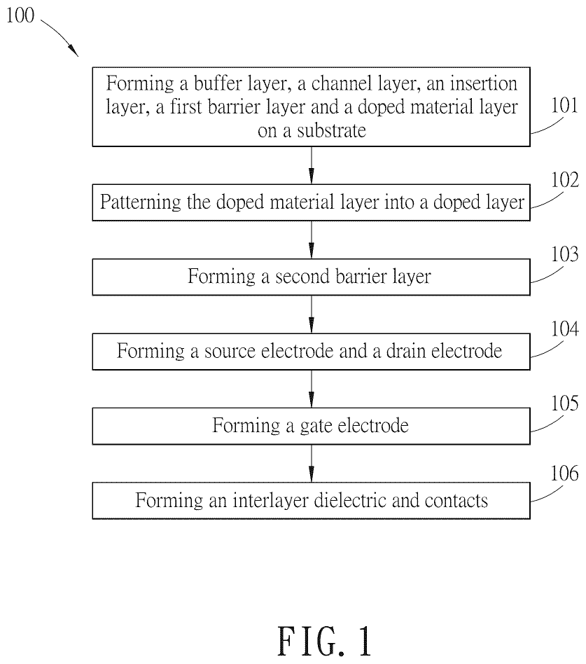

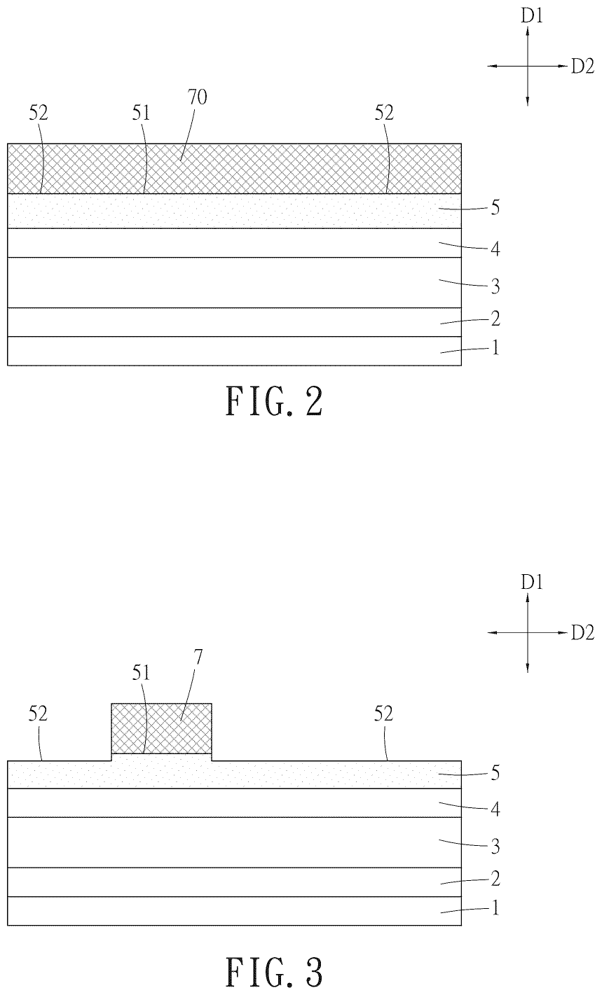

FIG. 1 is a flow diagram illustrating a method 100 for manufacturing the semiconductor structure, for example, the semiconductor structure 200 shown in FIG. 7, in accordance with some embodiments. FIGS. 2 to 7 illustrate schematic views of intermediate stages of the method 100 in accordance with some embodiments. Some repeating structures are omitted in FIGS. 2 to 7 for the sake of brevity.

Referring to FIG. 1 and the example illustrated in FIG. 2, the method 100 begins at step 101, where a buffer layer 2, a channel layer 3, an insertion layer 4, a first barrier layer 5 and a doped material layer 70 are sequentially formed on a substrate 1 along a first direction D1. Each of the buffer layer 2, the channel layer 3, the insertion layer 4, the first barrier layer 5 and the doped material layer 70 is formed by an epitaxy growing process or other suitable process.

A material of the substrate 1 may be determined according to practical needs. In some embodiments, the substrate 1 is a silicon substrate. In certain embodiments, the substrate 1 is a silicon carbide substrate. In other embodiments, the substrate 1 is a sapphire substrate. Other suitable materials for forming the substrate 1 are within the contemplated scope of the present disclosure.

The buffer layer 2 is configured to adjust stress, and to compensate lattice mismatch between the substrate 1 and the channel layer 3 (see FIG. 7). The buffer layer 2 may include aluminum nitride, aluminum gallium nitride, gallium nitride, or the likes, or combinations thereof. Other suitable materials for forming the buffer layer 2 are within the contemplated scope of the present disclosure. Please note that the buffer layer 2 may be omitted in certain embodiments.

The channel layer 3 is made of a first semiconductor material. In some embodiments, the first semiconductor material includes or is made of gallium nitride (GaN). In certain embodiments, the channel layer 3 is an undoped GaN layer.

The insertion layer 4 may be made of aluminum nitride. In some embodiments, the insertion layer 4 may be omitted according to practical needs.

The first barrier layer 5 is made of a second semiconductor material different from the first semiconductor material. The second semiconductor material has a band gap different from a band gap of the first semiconductor material. In some embodiments, the second semiconductor material is aluminum gallium nitride (AlGaN). In some embodiments, the first barrier layer 5 is made of a material represented by Alₓ₁Ga₁₋ₓ₁N, wherein x1 is smaller than 1.

The doped material layer 70 may be a p-type doped layer. In some embodiments, the doped material layer 70 is made of GaN, and a p-type dopant includes zinc, iron, carbon, magnesium, other suitable materials, or combinations thereof. In certain embodiments, magnesium is employed as a dopant of the doped material layer 70, at a concentration ranging from about 1×10¹⁷ atom/cm³ to about 1×10²² atom/cm³. Other suitable materials, and/or dopants, and/or doping concentration for forming the doped material layer 70 are within the contemplated scope of the present disclosure.

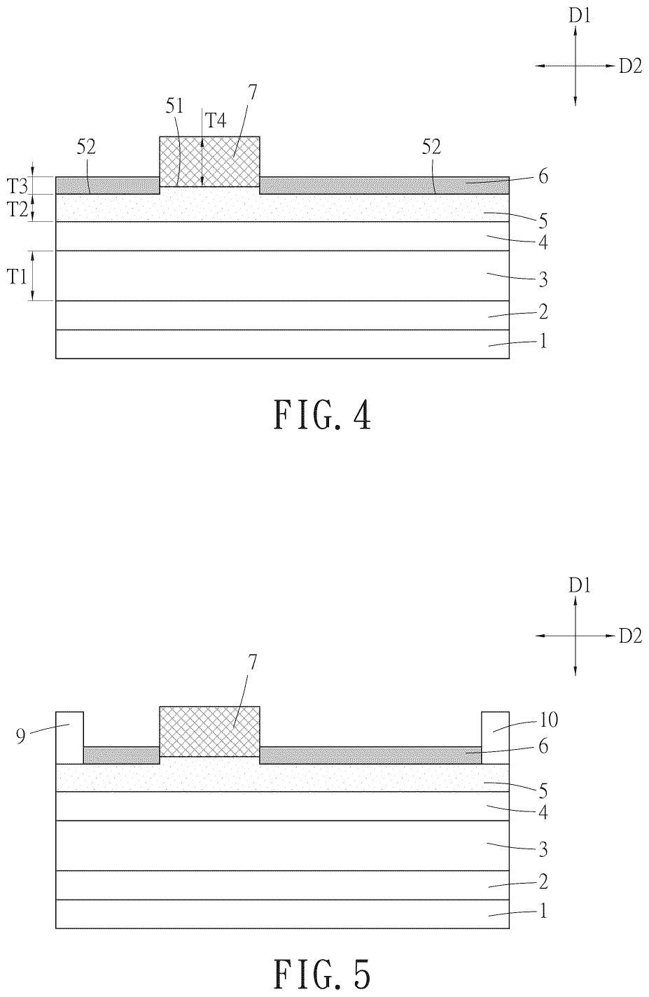

One may determine thickness of each of the abovementioned layers according to practical needs. For instance, the channel layer 3 may have a thickness (T1, see FIG. 4) greater than approximately 1 μm. The first barrier layer 5 may have a thickness (T2, see FIG. 4) ranging from about 1 nm to about 100 nm. The doped material layer 70 may have a thickness (T4, see FIG. 4, the doped layer 70 will be subsequently patterned and denoted by the numeral 7 in FIG. 4) greater than approximately 20 nm. Other suitable dimensions are within the contemplated scope of the present disclosure. The thickness of the different elements could be confirmed by a transmission electron microscope (TEM) image of the semiconductor structure 200.

Referring to FIG. 1 and the example illustrated in FIG. 3, the method 100 proceeds to step 102, where the doped material layer 70 (see FIG. 2) is patterned and is formed into a doped layer 7.

Specifically, in step 101, the doped material layer 70 (see FIG. 2) is formed on an upper surface of the first barrier layer 5 opposite to the substrate 1, covering both a first portion 51 and a second portion 52 of the upper surface of the first barrier layer 5. Location of the first portion 51 and the second portion 52 may be determined according to practical need. In the patterning process of step 102, the doped material layer 70 located at the first portion 51 of the upper surface is masked and remains, while the doped material layer 70 located at the second portion 52 is removed to expose the second portion 52.

The patterning process may employ any suitable photolithography processes and etching processes, and/or other suitable processes. Please note that one should ensure complete removal of the doped material layer 70 located at the second portion 52. In some embodiments, optionally, a surface part of the first barrier layer 5 located at the second portion 52 is also etched and removed as shown in FIG. 3, so as to achieve the complete removal of the doped material layer 70 located at the second portion 52 of the first barrier layer 5.

By completing step 102, the doped material layer 70 is formed into the doped layer 7, which covers the first portion 51 of the upper surface of the first barrier layer 5. The second portion 52 of the upper surface of the first barrier layer 5 is exposed from the doped layer 7.

Referring to FIG. 1 and the example illustrated in FIG. 4, the method 100 proceeds to step 103, where a barrier unit, which includes a second barrier layer 6, is formed on the first barrier layer 5. The second barrier layer 6 is formed by a selective epitaxy growing process or other suitable process. The barrier unit is formed to be displaced from the doped layer 7.

Some chemical elements included in the second barrier layer 6 are also included in the first barrier layer 5, but with different compositions in terms of aluminum content thereof. For instance, the second barrier layer 6 has an aluminum content greater than an aluminum content of the first barrier layer 5. In some embodiments, the second barrier layer 6 is made of a material represented by Alₓ₂Ga₁₋ₓ₂N, wherein x2 is greater than x1, and is smaller than or equal to 1. In some embodiments, x2 ranges from about 0.6 to about 1, from about 0.7 to about 1, from about 0.8 to about 1, or from about 0.9 to about 1.

Specifically, the second barrier layer 6 is formed over the exposed second portion 52 of the upper surface of the first barrier layer 5. The second barrier layer 6 is formed aside the doped layer 7. In some embodiments, the barrier unit is connected to the doped layer 7, i.e., a sidewall of the second barrier layer 6 faces and is connected to a sidewall of the doped layer 7. That is, the second barrier layer 6 of the barrier unit is in direct contact with the doped layer 7 in a second direction D2 transverse (e.g., perpendicular) to the first direction D1. A bottom surface of the second barrier layer 6 is at a level not higher than a level of a bottom surface of the doped layer 7. In some embodiments, as shown in FIG. 4, the bottom surface of the second barrier layer 6 is at a level slightly lower than that of the bottom surface of the doped layer 7 as a result of etching the surface part of the first barrier layer 5 in step 102 (see FIG. 3). The second barrier layer 6 may be formed as an ultrathin layer in view of the critical thickness limitation thereof. In some embodiments, the second barrier layer 6 has a thickness T3 (see FIG. 4, not drawn in scale) ranging from about 0.05 nm to about 60 nm. Please note that, when the second barrier layer 6 is too thick, e.g., larger than about 60 nm, the second barrier layer 6 may be prone to cracking or defects may be formed in the second barrier layer 6.

Referring to FIG. 1 and the example illustrated in FIG. 5, the method 100 proceeds to step 104, where a source electrode 9 and a drain electrode 10 are formed.

The source electrode 9 and the drain electrode 10 each extends through the second barrier layer 6 to reach the first barrier layer 5. In some embodiments, a bottom surface of each of the source electrode 9 and the drain electrode 10 is at a level flush with a bottom surface of the second barrier layer 6. In some embodiments, a sidewall of each of the source electrode 9 and the drain electrode 10 faces and is in direct contact with the second barrier layer 6. In addition, the source electrode 9 and the drain electrode 10 are formed to be spaced apart from each other. In some embodiments, the source electrode 9 and the drain electrode 10 are located on opposite sides of the doped layer 7.

In some embodiment, each of the source electrode 9 and the drain electrode 10 has a schottky contact or an ohmic contact with the first barrier layer 5. Each of the source electrode 9 and the drain electrode 10 may be independently made of a material including tantalum nitride (TaN), aluminum (Al), or copper (Cu), other suitable materials, or combinations thereof, but are not limited thereto. In other embodiments, each of the source electrode 9 and the drain electrode 10 may be independently made of a material including nickel silicon (NiSi), cobalt silicon (CoSi), molybdenum (Mo), tungsten (W), cobalt (Co), zirconium (Zr), platinum (Pt), other suitable materials, or combinations thereof.

In some embodiments, step 104 may include removing portions of the second barrier layer 6 by e.g., a patterning process or other suitable process, to expose desired portions of the first barrier layer 5, followed by forming the source electrode 9 and the drain electrode 10 respectively on the exposed portions of the first barrier layer 5. Other suitable materials, and/or configurations, and/or methods for forming the source electrode 9 and the drain electrode 10 are within the contemplated scope of the present disclosure.

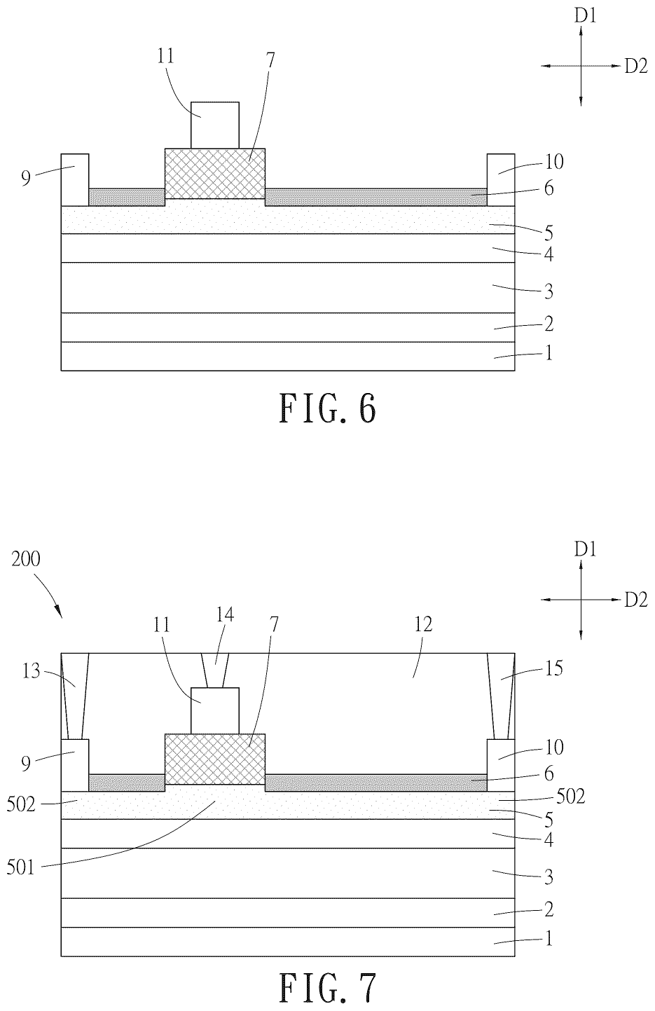

Referring to FIG. 1 and the example illustrated in FIG. 6, the method 100 proceeds to step 105, where a gate electrode 11 is formed.

The gate electrode 11 is formed on the doped layer 7 opposite to the first barrier layer 5. The gate electrode 11 forms a schottky contact or an ohmic contact with the doped layer 7. The gate electrode 11 is made of a material similar to that of the source electrode 9 and the drain electrode 10, and details thereof are omitted for the sake of brevity.

In some embodiments, step 105 further includes, prior to forming the gate electrode 11, forming a gate dielectric (not shown) on the doped layer 7, such that the gate electrode 11 is spaced apart from the doped layer 7 by the gate dielectric. The gate dielectric may include a suitable dielectric material, such as silicon oxide, silicon nitride, silicon oxynitride, hafnium oxide, other suitable materials, or combinations thereof, but is not limited thereto.

Referring to FIG. 1 and the example illustrated in FIG. 7, the method 100 proceeds to step 106, where an interlayer dielectric (ILD) 12, and contacts 13, 14, 15 are formed.

In some embodiments, step 106 includes sub-steps of: forming the ILD 12 over the structure shown in FIG. 6; forming the contacts 13 and 15 in the ILD 12 such that the contacts 13 and 15 are respectively connected to the source electrode 9 and the drain electrode 10; and then forming the contact 14 in the ILD 12 such that the contact 14 is connected to the gate electrode 11. In some other embodiments, the contact 14 may be formed first, followed by forming the contacts 13 and 15. The ILD 12 may include a dielectric material, such as silicon oxide, or the like, or combination thereof, but is not limited thereto. Each of the contacts 13, 14, 15 may include any suitable electrically conducting material, such as aluminum, titanium, tantalum, cobalt, copper, tungsten, ruthenium or the likes, or combinations thereof, but are not limited thereto. Other suitable materials and/or methods for forming the ILD 12 and the contacts 13, 14, 15 are within the contemplated scope of the present disclosure. By completing step 106, the semiconductor structure 200 is obtained.

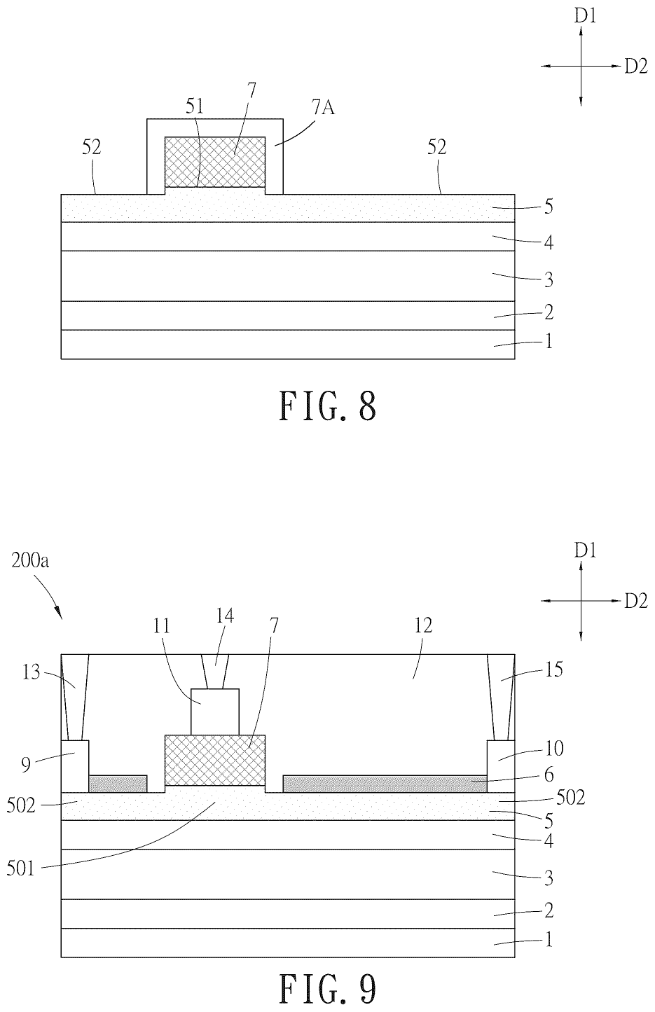

In the method 100, additional steps can be provided before, after or during the method, and some of the steps described herein may be replaced by other steps or be eliminated. For example, as shown in FIG. 8, before step 103, a mask layer 7A is formed to cover the doped layer 7, and the mask layer 7A will be removed after forming the second barrier layer 6. Therefore, in this case, after step 106, a semiconductor structure 200a shown in FIG. 9 is obtained. In the semiconductor structure 200a, the second barrier layer 6 is spaced apart from the doped layer 7.

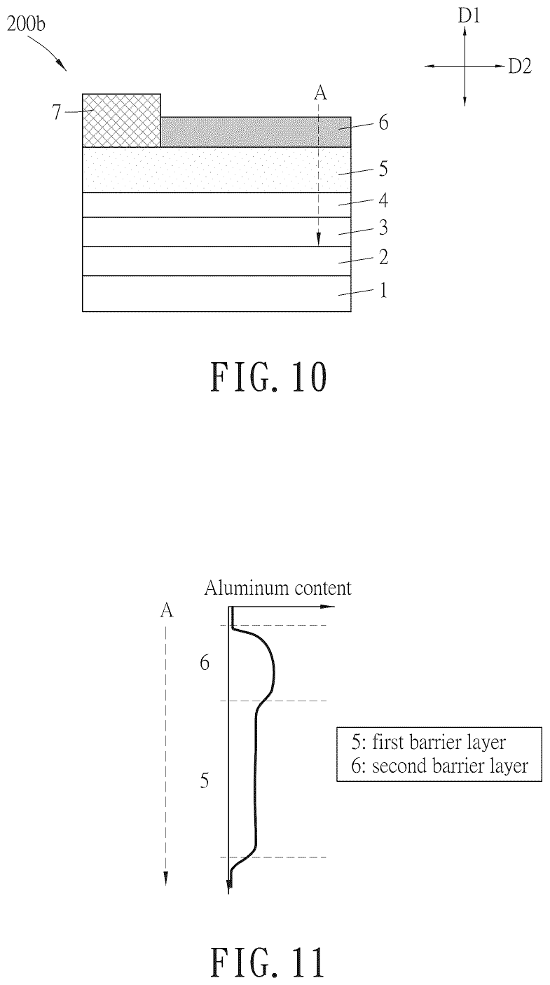

FIG. 10 shows a semiconductor structure 200b in accordance with some embodiments of the present disclosure. The semiconductor structure 200b is similar to the semiconductor structure 200, except that the bottom surface of the second barrier layer 6 is flush with the bottom surface of the doped layer 7.

As described above, the first dielectric layer 5 includes the material represented by Alₓ₁Ga₁₋ₓ₁N and the second barrier layer 6 includes the material represented by Alₓ₂Ga₁₋ₓ₂N, wherein x2 is greater than x1. The aluminum content, i.e., value of x1, x2 may be confirmed by conducting an energy-dispersive X-ray spectroscopy (EDS) analysis (or secondary-ion mass spectrometry (SIMS)). For the exemplary embodiment shown in FIG. 10, an EDS analysis is conducted along a direction illustrated by a dashed arrow (A) (i.e., in a direction from an upper surface of the second barrier layer 6 toward a bottom surface of the first barrier layer 5), and the result is shown in FIG. 11. FIG. 11 is an EDS line graph showing the aluminum content in the first and second barrier layers 5, 6 (the aluminum content of the other elements of the semiconductor structure 200b are not shown). As shown in FIG. 11, the second barrier layer 6 generally has an aluminum greater than the first barrier layer 5. Within the second barrier layer 6, in a direction away from an upper surface of the second barrier layer 6, the aluminum content increases, and then decreases in a direction toward a bottom surface of the second barrier layer 6. Within the first barrier layer 5, in a direction away from an upper surface of the first barrier layer 5, the aluminum content first slightly decreases, then remains substantially the same, and then slightly decreases.

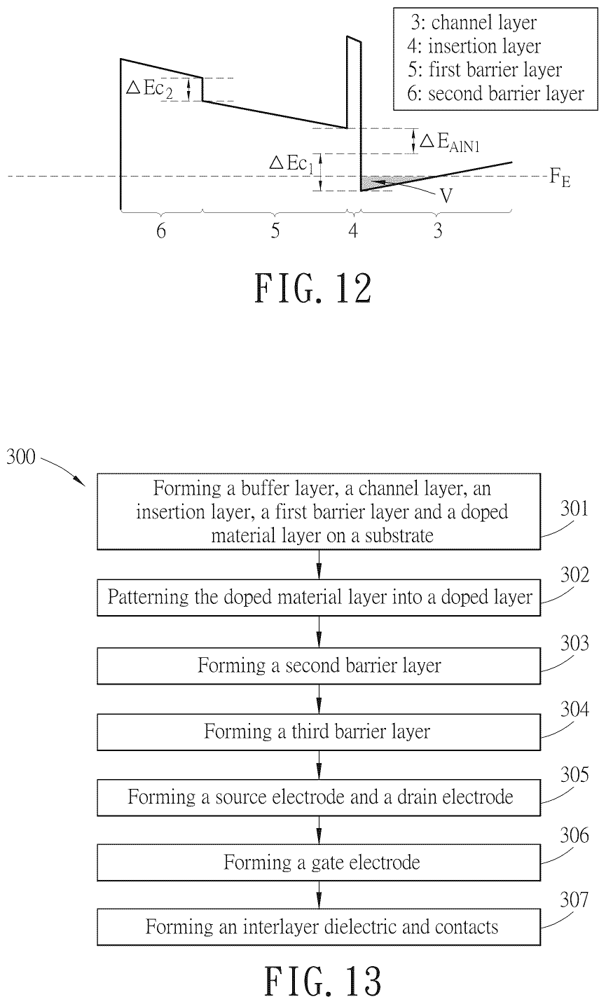

It is believed that including the second barrier layer 6, in addition to the first barrier layer 5, is beneficial to improving performance of the semiconductor structures 200, 200a, and 200b. The first barrier layer 5 and the second barrier layer 6 cooperatively serve as an AlGaN-based barrier structure to form a heterojunction with the GaN-based channel layer 3. Polarization due to material properties of AlGaN and GaN gives rise to formation of a two dimension gas electron (2DEG) at an interface of the heterojunction. That is, electrons are confined, at a high density, at an interface between the barrier structure (i.e., the first and second barrier layers 5, 6) and the channel layer 3. The 2DEG may be considered a quantum well. FIG. 12 is a schematic band diagram illustrating conduction bands of the second barrier layer 6, the first barrier layer 5, the insertion layer 4, and the channel layer 3 of the semiconductor structure 200b. A dashed line (FE) shown in FIG. 12 denotes Fermi energy level. The 2DEG is shown by a valley (V) formed at the interface of the barrier structure (i.e., the first and second barrier layers 5, 6) and the channel layer 3 below the Fermi energy level. In addition, it can be seen that the conduction bands of the first barrier layer 5 and the second barrier layer 6 are much higher than the conduction band of the channel layer 3, i.e., a conduction band offset (may be known as effective ΔEc) between the barrier structure and the channel layer 3 is large, and is equivalent to ΔEc₁+ΔE_{AlN1}. It is noted that the second barrier layer 6, which has a greater aluminum content than that of the first barrier layer 5, has a conduction band greater than the first barrier layer 5 by ΔEc₂. As such, the second barrier layer 6 helps to increase the conduction band offset between the barrier structure and the channel layer 3. The polarization effect is enhanced to increase electron confinement at the heterojunction (i.e., electron density at the 2DEG is increased, resulting in the steep valley (V) as shown in FIG. 12), as well as mobility of electrons. Moreover, the increased electron density reduces resistance, and alleviates influence of alloy scattering. ΔEc₁ represents a conduction band offset in case of absence of the insertion layer 4. In presence of the insertion layer 4 made of AlN, the conduction band offset between the barrier structure and the channel layer 3 further increases by ΔE_{AlN1}, thereby showing that the insertion layer 4 helps to confine electrons at the heterojunction, i.e., the interface between the channel layer 3, and the first and second barrier layers 5, 6.

The doped layer 7 made of p-GaN is configured to reduce polarization at the heterojunction, so as to deplete the 2DEG, such that the semiconductor structures 200, 200a, 200b are kept normally off. The description “normally off” refers to the channel layer 3 of the semiconductor structures 200, 200a, 200b being non-conducting when no gate bias is applied to the doped layer 7. As such, the semiconductor structures 200, 200a, 200b are each known as an enhancement mode high-electron-mobility transistor (E-HEMT).

The first barrier layer 5 has a first part 501 located beneath the gate electrode 14 (see FIG. 7), and a second part 502 located beneath the source electrode 9 or the drain electrode 10. In some embodiments, an aluminum content of the first part 501 is lower than an aluminum content of the second part 502, so as to permit the depleting of 2DEG beneath the gate electrode 14, and thus the semiconductor structures 200, 200a, 200b are kept normally off.

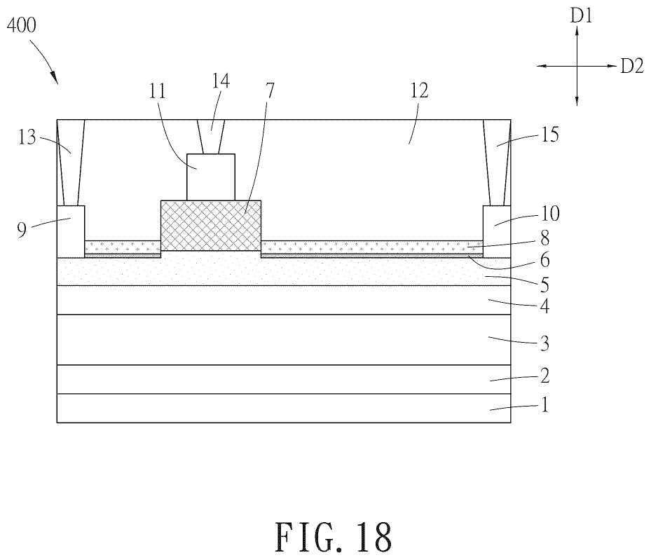

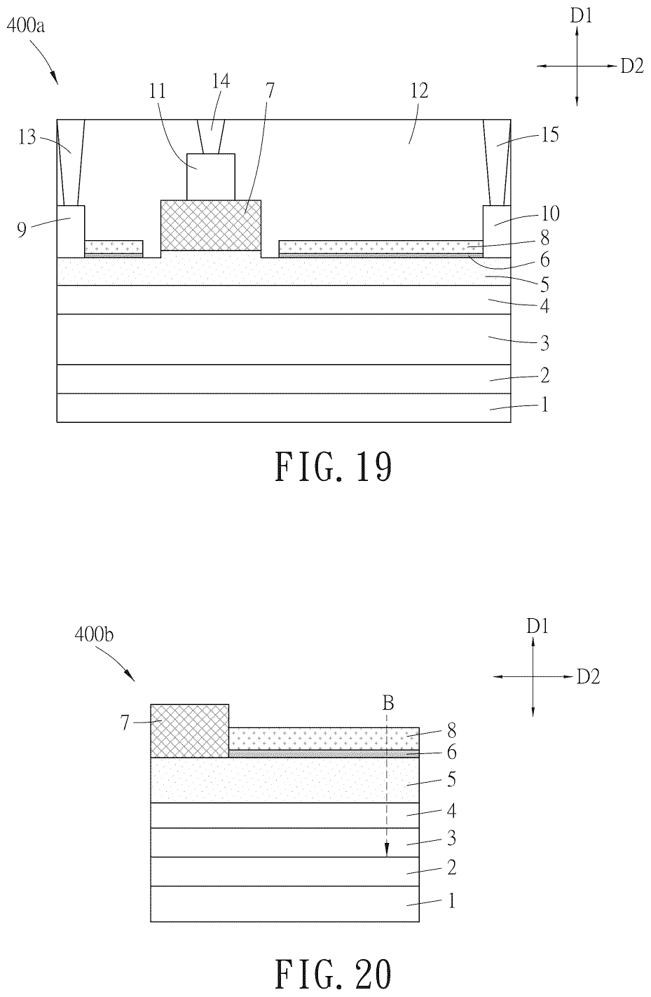

In accordance with some embodiments, the semiconductor structure may also include a third barrier layer in the barrier unit. The semiconductor structure 400 shown in FIG. 18, the semiconductor structure 400a shown in FIG. 19, and the semiconductor structure 400b shown in FIG. 20 are three exemplary embodiments that includes such barrier unit, in which the third barrier layer is denoted by the numeral 8. That is, the barrier structure of the semiconductor structure includes three of the barrier layers, namely, the first, second and third barrier layers 5, 6, 8 that may have different aluminum contents. In such case, the second barrier layer 6 has the highest aluminum content among the three barrier layers. The three-layered barrier structure could be confirmed by TEM, while the aluminum contents thereof could be confirmed by EDS or SIMS.

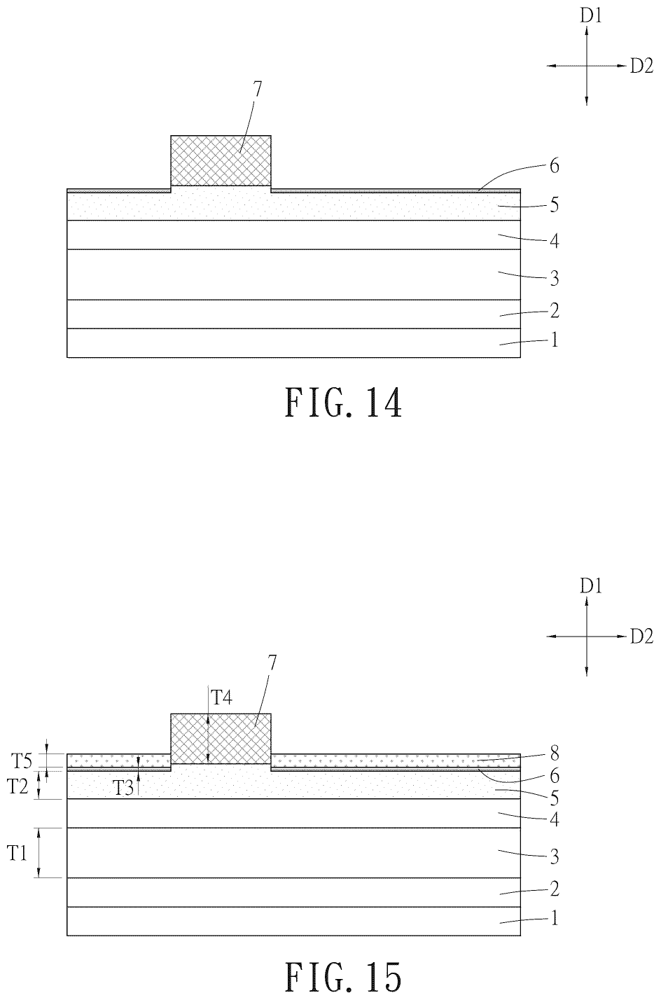

FIG. 13 is a flow diagram illustrating a method 300 for manufacturing the semiconductor structure, for example, the semiconductor structure 400 shown in FIG. 18, in accordance with some embodiments. The semiconductor structure 400 is similar to the semiconductor structure 200 as shown in FIG. 7, except that the semiconductor structure 400 further includes a third barrier layer 8 (see FIG. 18); and the method 300 is similar to the method 100, except that the method 300 further includes an additional step for forming the third barrier layer 8. FIGS. 14 to 18 illustrate schematic views of intermediate stages of the method 300 in accordance with some embodiments. Some repeating structures are omitted in FIGS. 14 to 18 for the sake of brevity.

Referring to FIG. 13, steps 301 and 302 of the method 300 are respectively identical to steps 101 (described with reference to FIGS. 2) and 102 (described with reference to FIG. 3) of the method 100, and thus details thereof are omitted for the sake of brevity.

Referring to FIG. 13 and the example illustrated in FIG. 14, the method 300 proceeds to step 303, where the second barrier layer 6 of the barrier unit is formed on the first barrier layer 5.

In the method 300, the barrier unit includes the second barrier layer 6 formed in step 303 and the third barrier layer 8 formed in step 304. Step 303 is similar to step 103 described with reference to FIG. 4 except that the second barrier layer 6 formed in step 303 has a thickness different from the second barrier layer 6 formed in step 103. Same as the second barrier layer 6 described in step 103, the second barrier layer 6 of step 303 is made of the material represented by Alₓ₂Ga₁₋ₓ₂N, wherein x2 is greater than x1, and is not greater than 1. In some embodiments, x2 ranges from about 0.6 to about 1, from about 0.7 to about 1, from about 0.8 to about 1, or from about 0.9 to about 1. In some embodiments, x2 equals to 1, i.e., the second barrier layer 6 may be an aluminum nitride (AlN) layer. The second barrier layer 6 may be formed as an ultrathin layer in view of the critical thickness limitation thereof. In some embodiments, the second barrier layer 6 has a thickness T3 (see FIG. 15) ranging from about 0.05 nm to about 20 nm. Please note that, when the second barrier layer 6 is too thick, e.g., larger than about 20 nm, the second barrier layer 6 may be prone to cracking or defects may be formed in the second barrier layer 6.

In some embodiments, as shown in FIG. 14, the bottom surface of the second barrier layer 6 is at a level lower than the bottom surface of the doped layer 7. In addition, an upper surface of the second barrier layer 6 is at a level lower than that of a bottom surface of the doped layer 7. In such case, the second barrier layer 6 is formed aside, but not connected to the doped layer 7. In other embodiments, the upper surface of the second barrier layer 6 is at a level higher than that of the bottom surface of the doped layer 7 (see FIG. 20), and in such case, the second barrier layer 6, is in direct contact with the doped layer 7 by having the sidewall of the second barrier layer 6 facing and being connected to the sidewall of the doped layer 7 in the second direction D2. Other details of step 303 are similar to step 103, and details thereof are omitted for the sake of brevity.

Referring to FIG. 13 and the example illustrated in FIG. 15, the method 300 proceeds to step 304, where the third barrier layer 8 of the barrier unit is formed on the second barrier layer 6. In some embodiments, the third barrier layer 8 is formed by an epitaxy growing process or other suitable processes.

The third barrier layer 8 is formed on the second barrier layer 6 opposite to the first barrier layer 5. The chemical elements included in the third barrier layer 8 are also included in the first barrier layer 5, but with different composition in terms of aluminum content thereof. Specifically, the third barrier layer 8 is made of a material represented by Alₓ₃Ga₁₋ₓ₃N, wherein x3 is smaller than x2, and is greater than or equal to x1. That is, the third barrier layer 8 has an aluminum content smaller than that of the second barrier layer 6. The third barrier layer 8 may have a thickness (T5) not greater than approximately 60 nm. Please note that, when the third barrier layer 8 is too thick, e.g., larger than about 60 nm, the third barrier layer 8 may be prone to cracking or defects may be formed in the third barrier layer 8.

The third barrier layer 8 is formed aside the doped layer 7. In some embodiments, as shown in FIG. 15, a sidewall of the third barrier layer 8 faces and is connected to the sidewall of the doped layer 7. That is, the third barrier layer 8 is in direct contact with the doped layer 7 in the second direction D2.

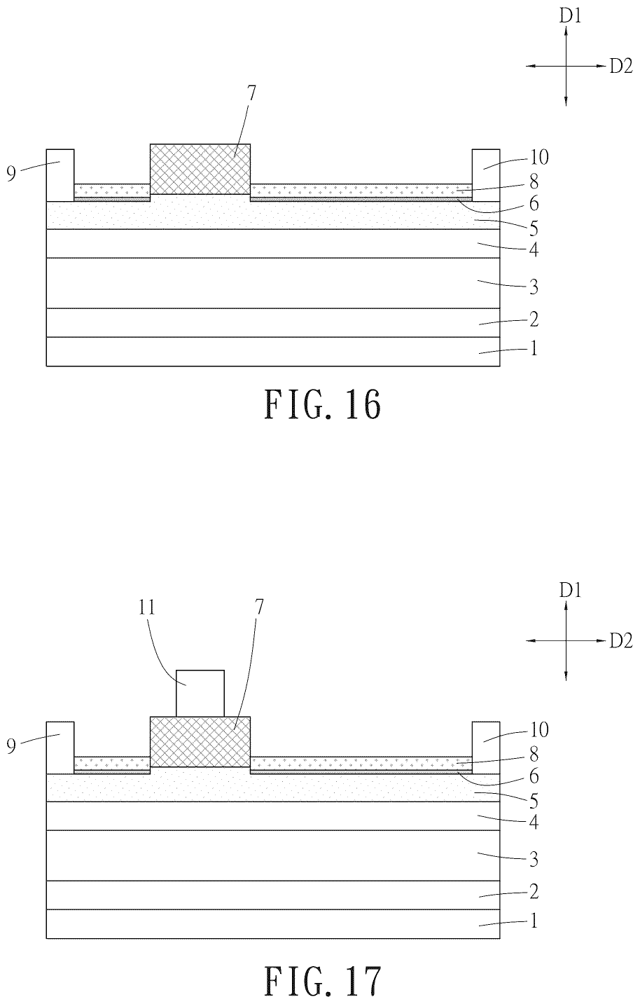

Referring to FIG. 13 and the example illustrated in FIG. 16, the method 300 proceeds to step 305, where a source electrode 9 and a drain electrode 10 are formed.

Step 305 is similar to step 104 described with reference to FIG. 5, except that the source electrode 9 and the drain electrode 10 each extend through both the second barrier layer 6 and the third barrier layer 8 to reach the first barrier layer 5. In additions, sidewalls of each of the source electrode 9 and the drain electrode 10 face and are in direct contact with both the second barrier layer 6 and the third barrier layer 8. Other details of step 305, such as materials and processes for forming the source electrode 9 and the drain electrode 10 are similar to those of step 104 and thus are omitted for the sake of brevity.

Referring to FIG. 13 and the example illustrated in FIGS. 17 to 18, the method 300 proceeds to step 306, where a gate electrode 11 is formed (see FIG. 17); and then proceeds to step 307, where an ILD 12, and contacts 13, 14, 15 (see FIG. 18) are formed. Step 306 and step 307 are respectively similar to step 105 (described with reference to FIG. 6) and step 106 (described with reference to FIG. 7), and thus details thereof are omitted for the sake of brevity. By completing step 307, the semiconductor structure 400 is obtained.

In the method 300, additional steps can be provided before, after or during the method, and some of the steps described herein may be replaced by other steps or be eliminated. For example, as shown in FIG. 8, before step 303, a mask layer 7A is formed to cover the doped layer 7, and the mask layer 7A will be removed after forming the third barrier layer 8. Therefore, in this case, after step 307, a semiconductor structure 400a shown in FIG. 19 is obtained. In the semiconductor structure 400a, both the second barrier layer 6 and the third barrier layer 8 are spaced apart from the doped layer 7.

FIG. 20 shows the semiconductor structure 400b in accordance with some embodiments of the present disclosure. The semiconductor structure 400b is similar to the semiconductor structure 200b shown in FIG. 10, except that the semiconductor structure 400b further includes the third barrier layer 8. The semiconductor structure 400b is similar to the semiconductor structure 400 shown in FIG. 18, except that in the semiconductor structure 400b, the bottom surface of the second barrier layer 6 is flush with the bottom surface of the doped layer 7.

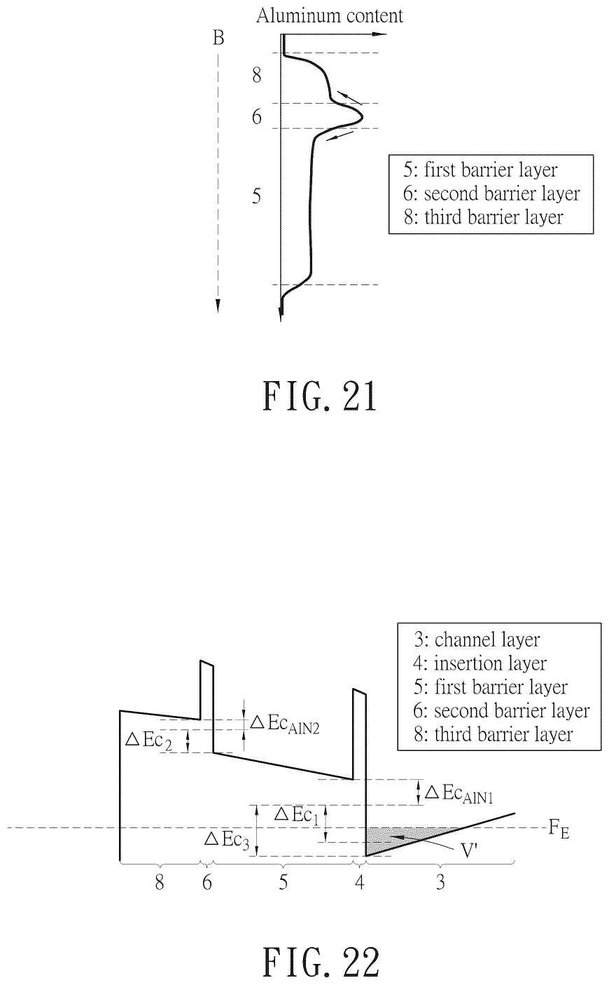

For the exemplary embodiment shown in FIG. 20, an EDS analysis is conducted along a direction illustrated by a dashed arrow (B), and the result is shown in FIG. 21. FIG. 21 is an EDS line graph showing the aluminum content in the first, second and third barrier layers 5, 6, 8. It is evident that the second barrier layer 6, serving as an intermediate layer interposed between the first and third barrier layers 5, 8, has the highest aluminum content. The aluminum content gradually decreases in directions away from the second barrier layer 6 (see the two solid arrows in FIG. 21), indicating the lower aluminum content in each of the first and third barrier layers 5, 8. In addition, it is clear that the third barrier layer 8 generally has an aluminum content higher than the first barrier layer 5. Such first, second, and third barrier layers 5, 6, 8 cooperatively form the AlGaN-based barrier structure of the semiconductor structure 400b.

FIG. 22 is a schematic band diagram illustrating conduction bands of the third barrier layer 8, the second barrier layer 6, the first barrier layer 5, the insertion layer 4, and the channel layer 3 of the semiconductor structure 400b. A peak appears at the second barrier layer 6, which has the highest aluminum content among the three barrier layers 5, 6, 8. As a result, the third barrier layer 8 has a conduction band greater than that of the first barrier layer 5 by ΔEc₂+ΔEc_{AlN2}, in which ΔEc₂ is same as that of FIG. 12. The configuration of the second and third barrier layers 6, 8 helps achieve an even greater conduction band offset between the barrier structure of the semiconductor structure 400b and the channel layer 3 in comparison with the band diagram (of the semiconductor structure 200b) shown in FIG. 12. Specifically, the conduction band offset between the barrier structure and the channel layer 3 is ΔEc₃+ΔE_{AlN1}, in which ΔEc₃ represents a conduction band offset in case of absence of the insertion layer 4, and ΔEc₃ is larger than ΔEc₁ as illustrated in FIG. 12. In addition, such larger conduction band offset results in an even steeper valley (V′) compared with the valley (V) of FIG. 12, i.e., the lowest point of the band diagram is shifted downwardly to an even lower position. It is clear that the polarization of the barrier structure of the semiconductor structures 400, 400a and 400b is enhanced to further improve electron confinement at the heterojunction comparing with the semiconductor structures 200, 200a and 200b. That is, electron density at the 2DEG of the semiconductor structures 400, 400a and 400b is further enhanced, so as to, further improve mobility of electrons and alleviate alloy scattering.

The configuration of the first, second and third barrier layers 5, 6, 8, along with the specified ranges of aluminum contents, permits the semiconductor structures 400, 400a, 400b of the present disclosure to have improved electron confinement at the heterojunction. As a result, the semiconductor structures 400, 400a, 400b of the present disclosure has an improved performance, such as an increased breakdown voltage and dynamic on-state resistance thereof. For instance, the breakdown voltage (such as ranging from about 1400 V to about 1700 V) is found to be increased by as much as about 15%. In addition, the dynamic on-state resistance is found to be increased by as much as about 65% in the condition of applying about 5 V bias voltage to the semiconductor structures.

Please note that both the aluminum content and the thickness of each of the second barrier layer 6 and the third barrier layer 8 affect the conduction band offset between the barrier structure and the channel layer 3, as well as the electron confinement at the heterojunction, which in turn influence performance of the semiconductor structures 400, 400a, 400b, e.g., performance relating to breakdown voltage and dynamic on-state resistance. Within an optimized range as discussed above, increasing each of the aluminum content (i.e., x2) of the second barrier layer 6, the thickness (i.e., T3) of the second barrier layer 6, and the aluminum content (i.e., x3) of the third barrier layer 8 helps improve breakdown voltage and dynamic on-state resistance of the semiconductor structures, though such performance enhancements do not necessarily improve with thickness (i.e., T5) of the third barrier layer 8. One may optimize thickness of the third barrier layer 8, and the second barrier layer 6 according to a desired breakdown voltage and/or dynamic on-state resistance.

The embodiments of the present disclosure have the following advantageous features. The first, second and third barrier layers 5, 6, 8 formed with the specific aluminum content relationship (i.e., the relationship between x1, x2 and x3) and thickness ranges (i.e., T3, T5) as discussed permit the semiconductor structure to have greatly improved electron confinement, improved electron mobility at 2DEG of the heterojunction, and alloy scattering is found to be reduced. Thus, the semiconductor structure of the present disclosure is capable to achieve significantly enhanced performance in terms of improved breakdown voltage and dynamic on-state resistance (which may be adjusted by altering the aluminum content and the thickness of each of the second and/or third barrier layers 6, 8).

In accordance with some embodiments of the present disclosure, a method for manufacturing a semiconductor structure includes: forming a channel layer on a substrate; forming a first barrier layer on the channel layer opposite to the substrate, the first barrier layer having an upper surface opposite to the substrate, and being made of a material represented by Alₓ₁Ga₁₋ₓ₁N; forming a doped layer on a first portion of the upper surface of the first barrier layer, so that a second portion of the upper surface of the first barrier layer is exposed from the doped layer; forming a second barrier layer over the second portion of the upper surface of the first barrier layer, the second barrier layer being made of a material represented by Alₓ₂Ga₁₋ₓ₂N, x2 being greater than x1; and forming a third barrier layer on the second barrier layer opposite to the first barrier layer, the third barrier layer being made of a material represented by Alₓ₃Ga₁₋ₓ₃N, x3 being smaller than x2.

In accordance with some embodiments of the present disclosure, a bottom surface of the second barrier layer is at a level not higher than a level of a bottom surface of the doped layer.

In accordance with some embodiments of the present disclosure, a sidewall of the second barrier layer faces and is connected to a sidewall of the doped layer.

In accordance with some embodiments of the present disclosure, a sidewall of the third barrier layer faces and is connected to a sidewall of the doped layer.

In accordance with some embodiments of the present disclosure, the second barrier layer and the third barrier layer are spaced apart from the doped layer.

In accordance with some embodiments of the present disclosure, the second barrier layer and the third barrier layer are formed after forming the doped layer.

In accordance with some embodiments of the present disclosure, x2 equals to 1.

In accordance with some embodiments of the present disclosure, x3 is greater than or equal to x1.

In accordance with some embodiments of the present disclosure, a thickness of the second barrier layer ranges from 0.05 nm to 20 nm.

In accordance with some embodiments of the present disclosure, forming the doped layer includes: forming a doped material layer covering both the first portion and the second portion of the upper surface of the first barrier layer; and patterning the doped material layer to form the doped layer.

In accordance with some embodiments of the present disclosure, a method for manufacturing a semiconductor structure, sequentially includes: forming a channel layer on a substrate; forming a first barrier layer on the channel layer, the first barrier layer being made of a material represented by Alₓ₁Ga₁₋ₓ₁N; forming a doped layer on the first barrier layer; forming a second barrier layer over the first barrier layer opposite to the channel layer, the second barrier layer being made of a material represented by Alₓ₂Ga₁₋ₓ₂N, x2 being greater than x1; and forming a third barrier layer on the second barrier layer opposite to the first barrier layer, the third barrier layer being made of a material represented by Alₓ₃Ga₁₋ₓ₃N, x3 being smaller than x2.

In accordance with some embodiments of the present disclosure, the second barrier layer is formed aside and connected to the doped layer.

In accordance with some embodiments of the present disclosure, the third barrier layer is formed aside and connected to the doped layer.

In accordance with some embodiments of the present disclosure, the method further includes: forming a source electrode and a drain electrode that are located on opposite sides of the doped layer, each of the source electrode and the drain electrode extending through the second barrier layer to reach the first barrier layer; and forming a gate electrode that is located on the doped layer opposite to the first barrier layer.

In accordance with some embodiments of the present disclosure, each of the source electrode and the drain electrode forms a schottky contact or an ohmic contact with the first barrier layer, and the gate electrode forms a schottky contact or an ohmic contact with the doped layer.

In accordance with some embodiments of the present disclosure, the first barrier layer has a first part located beneath the gate electrode, and a second part located beneath the source electrode or the drain electrode, an aluminum content of the first part being lower than an aluminum content of the second part.

In accordance with some embodiments of the present disclosure, a bottom surface of each of the source electrode and the drain electrode is at a level flush with a bottom surface of the second barrier layer.

In accordance with some embodiments of the present disclosure, a semiconductor structure includes: a channel layer; a first barrier layer disposed on the channel layer; a barrier unit; and a doped layer. The barrier unit is disposed on the first barrier layer, and includes a second barrier layer and a third barrier layer. The second barrier layer is disposed on the first barrier layer opposite to the channel layer, and has an aluminum content greater than an aluminum content of the first barrier layer. The third barrier layer is disposed on the second barrier layer opposite to the first barrier layer and has an aluminum content smaller than the aluminum content of the second barrier layer. The doped layer is disposed on the first barrier layer along a first direction, and displaced from the barrier unit in a second direction transverse to the first direction.

In accordance with some embodiments of the present disclosure, the barrier unit is in direct contact with the doped layer.

In accordance with some embodiments of the present disclosure, the doped layer is a p-type doped layer.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a channel layer on a substrate;
forming a first barrier layer on the channel layer opposite to the substrate, the first barrier layer having an upper surface opposite to the substrate, and being made of a material represented by Alₓ₁Ga₁₋ₓ₁N;
forming a doped layer on a first portion of the upper surface of the first barrier layer, so that a second portion of the upper surface of the first barrier layer is exposed from the doped layer;
forming a second barrier layer over the second portion of the upper surface of the first barrier layer, the second barrier layer being made of a material represented by Alₓ₂Ga₁₋ₓ₂N, x2 being greater than x1; and
forming a third barrier layer on the second barrier layer opposite to the first barrier layer, the third barrier layer being made of a material represented by Alₓ₃Ga₁₋ₓ₃N, x3 being smaller than x2.

2. The method according to claim 1, wherein a bottom surface of the second barrier layer is at a level not higher than a level of a bottom surface of the doped layer.

3. The method according to claim 1, wherein a sidewall of the second barrier layer faces and is connected to a sidewall of the doped layer.

4. The method according to claim 1, wherein a sidewall of the third barrier layer faces and is connected to a sidewall of the doped layer.

5. The method according to claim 1, wherein the second barrier layer and the third barrier layer are spaced apart from the doped layer.

6. The method according to claim 1, wherein the second barrier layer and the third barrier layer are formed after forming the doped layer.

7. The method according to claim 1, wherein x2 equals to 1.

8. The method according to claim 1, wherein x3 is greater than or equal to x1.

9. The method according to claim 1, wherein a thickness of the second barrier layer ranges from 0.05 nm to 20 nm.

10. The method according to claim 1, wherein forming the doped layer includes:
forming a doped material layer covering both the first portion and the second portion of the upper surface of the first barrier layer; and
patterning the doped material layer to form the doped layer.

11. A method for manufacturing a semiconductor structure, sequentially comprising:
forming a channel layer on a substrate;
forming a first barrier layer on the channel layer, the first barrier layer being made of a material represented by Alₓ₁Ga₁₋ₓ₁N;
forming a doped layer on the first barrier layer;
forming a second barrier layer over the first barrier layer opposite to the channel layer, the second barrier layer being made of a material represented by Alₓ₂Ga₁₋ₓ₂N, x2 being greater than x1; and
forming a third barrier layer on the second barrier layer opposite to the first barrier layer, the third barrier layer being made of a material represented by Alₓ₃Ga₁₋ₓ₃N, x3 being smaller than x2.

12. The method according to claim 11, wherein the second barrier layer is formed aside and connected to the doped layer.

13. The method according to claim 11, wherein the third barrier layer is formed aside and connected to the doped layer.

14. The method according to claim 11, the method further comprising:
forming a source electrode and a drain electrode that are located on opposite sides of the doped layer, each of the source electrode and the drain electrode extending through the second barrier layer to reach the first barrier layer; and
forming a gate electrode that is located on the doped layer opposite to the first barrier layer.

15. The method according to claim 14, wherein:
each of the source electrode and the drain electrode forms a schottky contact or an ohmic contact with the first barrier layer, and
the gate electrode forms a schottky contact or an ohmic contact with the doped layer.

16. The method according to claim 14, wherein the first barrier layer has a first part located beneath the gate electrode, and a second part located beneath the source electrode or the drain electrode, an aluminum content of the first part being lower than an aluminum content of the second part.

17. The method according to claim 14, wherein a bottom surface of each of the source electrode and the drain electrode is at a level flush with a bottom surface of the second barrier layer.

18. A semiconductor structure, comprising:
a channel layer;
a first barrier layer disposed on the channel layer;
a barrier unit disposed on the first barrier layer, the barrier unit including a second barrier layer and a third barrier layer, the second barrier layer being disposed on the first barrier layer opposite to the channel layer, and having an aluminum content greater than an aluminum content of the first barrier layer, the third barrier layer being disposed on the second barrier layer opposite to the first barrier layer and having an aluminum content smaller than the aluminum content of the second barrier layer; and
a doped layer disposed on the first barrier layer along a first direction, and displaced from the barrier unit in a second direction transverse to the first direction.

19. The semiconductor structure according to claim 18, wherein the barrier unit is in direct contact with the doped layer.

20. The semiconductor structure according to claim 18, wherein the doped layer is a p-type doped layer.
